(19) United States
(12) Patent Application Publication
(10) Pub. No.: US 2024/0262104 A1
(43) Pub. Date: Aug. 8, 2024

(54) DEIVCE AND METHOD FOR SEGMENTED PARALLEL DISPENSING

(71) Applicant: Fraunhofer-Gesellschaft zur Förderung der angewandten Forschung e.V., München (DE)

(72) Inventors: Maximilian POSPISCHIL, Freiburg (DE); Martin KUCHLER, Freiburg (DE); Martin BREITENBÜCHER, Freiburg (DE); Tim RIEBE, Freiburg (DE); Sebastian TEPNER, Freiburg (DE); Florian CLEMENT, Freiburg (DE); Maximilian WEIL, Freiburg (DE); Katharina GENSOWKI, Freiburg (DE); Ana JIMENEZ CARDOZO, Freiburg (DE)

(73) Assignee: Fraunhofer-Gesellschaft zur Förderung der angewandten Forschung e.V., München (DE)

(21) Appl. No.: 18/035,776

(22) PCT Filed: Oct. 28, 2021
(86) PCT No.: PCT/EP2021/080047

§ 371 Date: May 8, 2023

(30) Foreign Application Priority Data
Nov. 6, 2020 (DE) 102020129305.4

(51) Int. Cl. B41J 2/145; H01L 31/0224; H01L 31/18

(52) U.S. Cl. CPC B41J 2/145; H01L 31/022425; H01L 31/18

(57) ABSTRACT

A device (1) for parallel dispensing a print medium (10) onto a substrate, in particular for producing one or more conductor tracks on a semiconductor substrate, having a printing unit (6), which includes a plurality of dispenser nozzles for simultaneous discharge of the print medium (10), and having a drive (5), which is configured to generate a relative movement between the printing unit (6) and the substrate (4) in a movement direction (7). At least first usnd second dispenser nozzles are arranged spaced apart from one another transversely in relation to the movement direction (7). The first dispenser nozzle and a third dispenser nozzle are arranged spaced apart from one another along a common first longitudinal axis at a first nozzle spacing, and the first longitudinal axis runs parallel to the movement direction (7).

### CROSS-REFERENCE TO RELATED APPLICATIONS

This application is a 371 National Phase of International Application No. PCT/EP2021/080047, filed Oct. 28, 2021, which claims priority from German Patent Application No. 10 2020 129 305.4, filed Nov. 6, 2020, both of which are incorporated herein by reference as if fully set forth.

### TECHNICAL FIELD

The invention relates to a device for parallel dispensing of a print medium and to a method for parallel dispensing of a print medium.

### BACKGROUND

In industrial printing operations, in particular in the production of semiconductor structures, such as photovoltaic solar cells, it is often desirable to apply a print medium to a substrate, in particular a semiconductor substrate, in at least two parallel tracks. Such a print medium may be a printing paste, which contains in particular a dopant for doping one or more regions of the semiconductor structure, which serves to form a masking for subsequent process steps and/or which contains metal particles for forming a metallic contact structure.

In order to deposit the printing paste onto the substrate, the print medium is delivered to a plurality of dispenser nozzles of the printing unit by means of a pump unit, while the printing unit is displaced in a relative movement with a movement direction with respect to the substrate. In the process, the print medium passes out of the dispenser nozzles onto the surface of the substrate, wherein the dispenser nozzles each create a printed line, which runs in accordance with the movement direction of the relative movement on the substrate. In order to deposit a plurality of parallel printed lines on the substrate in a short amount of time, it is known to arrange at least two dispenser nozzles of a printing unit in such a way that they are spaced apart from one another transversely in relation to a movement direction. This makes it possible to generate only one straight relative movement, with at the same time more than just one printed line being created. Such a printing unit is known from DE 10 2013 223 250 A1.

To increase the productivity of industrial printing operations, it is desirable to reduce the time required to apply the entirety of all printed lines, in particular up to a total of 200 printed lines, to the substrate. One possible way of achieving this lies in the configuration of power drive means by which the speed at which the printing unit and the substrate to be printed are moved in relation to one another can be increased, while the printed lines are applied to the substrate. However, power drive means of this type are associated with high technical complexity and/or high costs.

### SUMMARY

The present invention is therefore based on the object of increasing the productivity of industrial printing operations and at the same time to keep the costs required for this low. This object is achieved by a device for parallel dispensing of a print medium and by a method, each having one or more of the fetures disclosed herein. Advantageous configurations are found in the description claims that follow.

The device according to the invention for parallel dispensing of a print medium onto a substrate, in particular for producing one or more conductor tracks on a semiconductor substrate, comprises a printing unit having a plurality of dispenser nozzles for simultaneous discharge of the print medium. The device according to the invention also comprises a drive means, which is configured to generate a relative movement between the printing unit and the substrate in a movement direction, wherein at least a first dispenser nozzle and a second dispenser nozzle are arranged spaced apart from one another transversely in relation to the movement direction.

It is essential for the device according to the invention that the first dispenser nozzle and a third dispenser nozzle of the printing unit are arranged spaced apart from one another along a common first longitudinal axis at a first nozzle spacing, wherein the first longitudinal axis runs parallel to the movement direction.

It is a finding of the applicant that is essential to the invention that the productivity of industrial printing methods can be considerably increased in comparison with known devices and methods by arranging the dispenser nozzles of a printing unit in dependence on the movement direction of the relative movement.

As is known per se from the prior art, an advantage is achieved in that the first and the second dispenser nozzle are arranged on the printing unit spaced apart from one another transversely in relation to the movement direction. When carrying out the relative movement, the print medium, which exits the first dispenser nozzle and the second dispenser nozzle, creates a first printed line and a second printed line, respectively, on the substrate. In this respect, the first printed line and the second printed line are spaced apart from one another in parallel in accordance with the spacing between the first and the second dispenser nozzle and have a dedicated first and second starting point, respectively, and a first and second end point, respectively.

It is fundamentally unimportant whether the first dispenser nozzle and the second dispenser nozzle are arranged at the same height in the movement direction, that is to say in a common row of dispenser nozzles that runs orthogonally in relation to the movement direction. Rather, the advantage of these transversely spaced-apart dispenser nozzles emerges in a known way from the fact that the printing unit and the substrate can be displaced in relation to one another in a single relative movement, wherein at the same time two parallel and spaced-apart printed lines are created.

The applicant's finding that is essential to the invention, however, relates to the arrangement of a third dispenser nozzle on the printing unit. It is arranged upstream or downstream of the first dispenser nozzle along the first longitudinal axis. This leads to a third printed line, running coaxially with the first printed line, being created in addition to the first and the second printed line during the relative movement between the printing unit and the substrate.

The essential advantage of this arrangement can be seen in the fact that the first and the third printed line can be applied to the substrate easily by suitable control of the drive means in such a way that said printed lines touch at a common contact point and the two printed lines create a continuous printed line or, in accordance with demand, are arranged spaced apart from one another by a gap or even with an overlap.

The first longitudinal axis is a pure orientation axis, which runs in fixed fashion on a surface of the printing unit and in particular during construction can serve for arrangement of at least the first and the third dispenser nozzle on the printing unit. Said arrangement of the first and the third dispenser nozzle can be characterized in that the first and the third dispenser nozzle are arranged along the first longitudinal axis on the basis of identical geometric features, such as their respective nozzle center point or a peripheral point of a nozzle opening.

It is also within the scope of the invention that at least the first and the third dispenser nozzle have different geometric features, on the basis of which they are arranged along the first longitudinal axis. To embody the finding according to the invention, in this respect it is sufficient for the first and the third dispenser nozzle, during the relative movement, to be arranged with their respective nozzle openings at least partially in line as viewed along the movement direction, with the result that a relative movement of the printing unit in relation to the substrate makes it possible to create theoretically an uninterrupted printed line with simultaneous discharge of the print medium through the first and the third dispenser nozzle.

The relative movement can be realized according to the invention in various ways, which depend on the configuration of the drive means and how it can be controlled in order to generate the relative movement.

In the simplest embodiment, the drive means is a linear unit having a linear guide and a driven carriage, by means of which either the printing unit or the substrate is moved relative to the other in a straight line. In this respect, the relative movement has a movement direction and a relative displacement travel. The movement direction emerges from the orientation of the linear guide and from the starting position and end position of the carriage moved thereon. The relative displacement travel is produced depending on the positions in which the printing unit is located at the beginning and ending of the printing operation.

In another embodiment, the drive means comprises multiple linear units or other positioning units, by means of which both the printing unit and the substrate can be moved in relation to one another at the same time or in succession in order to generate the relative movement. The movement direction here emerges from the direction in which the dispenser nozzles pass over the substrate during the relative movement. The relative displacement travel always corresponds to the length of a region which is passed over by a single dispenser nozzle. In this respect, it is unimportant what dispenser nozzle of the printing unit this is, since the dispenser nozzles are arranged fixedly on the dispenser unit and thus, at least in the case of a single-piece printing unit, all cover the same relative displacement travel.

Irrespective of the embodiment of the drive means, it is configured in such a way that the relative displacement travel for performing a printing operation can be set variably in terms of its entire length. In this respect, the relative displacement travel can correspond to the first nozzle spacing or, however, be smaller or larger than the latter.

By setting a relative displacement travel which corresponds to the first nozzle spacing, it is possible, by applying the print medium by means of the first and the third dispenser nozzle and the resulting first and third printed line, respectively, to create a cohesive printed line with a length exactly twice as long as the relative displacement travel. As a result, the productivity of the printing operation, at least in relation to the assembled printed line, is increased by 100% over known devices and methods. A particular advantage emerges as a result of the productivity increase in the case of the deposition of low-temperature pastes onto semiconductor substrates, the deposition of which is achievable with optimum results in terms of the quality of the printed lines created as a result optimally at approx. 200 millimeters per second. By the arrangement of at least two dispenser nozzles, it is possible not to change the optimum deposition rate and thus not to cause any reductions in quality in spite of a considerable increase in productivity.

By further increasing the number of dispenser nozzles along the first longitudinal axis to a number of nozzles of more than two, the productivity can be further increased, since the relative displacement travel required to create a continuous printed line is reduced by the same factor that corresponds to the number of dispenser nozzles arranged one behind another.

By setting a relative displacement travel which is greater than the first nozzle spacing, a continuous printed line with an overlap region can be created at least by the first and the third printed line. Such an assembly of two printed lines can be advantageous in particular when the printed lines are contact-making fingers for the electrical connection of a semiconductor substrate. Investigations by the applicant have shown that the formation of an overlap region between two coaxial printed lines improves the conductive properties of the resulting assembled printed line by reducing the ohmic resistance. If the semiconductor substrate is a solar cell that is to be produced, the increased conductive properties are also associated with improved electrical performance of the later solar cell.

By setting a relative displacement travel which is smaller than the first nozzle spacing, the first and the third printed line are arranged spaced apart from one another coaxially after ending the relative movement. This means that, although the first and the third printed line are each oriented along the first longitudinal axis, the first end point and the third starting point of the corresponding printed lines have a spacing in relation to one another which corresponds to the difference between the relative displacement travel that was set and the first nozzle spacing. If the substrate is a semiconductor substrate, such an arrangement at least of the first and the third printed line makes it possible to achieve easy segmentation of the solar cell, wherein the first and the third printed line are electrically contacted separately from one another.

Moreover, the configuration of the printing unit and the dispenser nozzles is fundamentally unimportant. In a simple embodiment, the printing unit can be in the form of a metallic printhead with a preferably cuboidal basic shape, in a manner known per se. In this respect, the dispenser nozzles can each be made directly in the printhead in the form of cylindrical or non-cylindrical bores or be arranged in such a bore in the form of connectors that can be plugged in. A pump device serves to deliver the print medium to the dispenser nozzles, which deliver the print medium to a surface of the substrate.

In an advantageous refinement, the first dispenser nozzle and the second dispenser nozzle are arranged along a common first transverse axis, wherein the first transverse axis runs orthogonally in relation to the movement direction and the first transverse axis delimits the printing unit in such a way that the printing unit is free of further dispenser nozzles on one side of the first transverse axis.

The first transverse axis, similarly to the first longitudinal axis, is a structural orientation axis which describes the arrangement of the first and the second dispenser nozzle on the printing unit in relation to the movement direction of the relative movement.

The advantage produced by the arrangement of the first and the second dispenser nozzle along the first transverse axis can be seen in the fact that the first and the second printed line each have a start and an end point, which are applied to the substrate at the same height in the movement direction. This is advantageous in particular for the production of metallic contact structures on semiconductor substrates, since in particular multiple start and end points arranged in this way can be electrically contacted by means of a common and straight busbar.

The profile of the first transverse axis is also advantageous both for the construction and for the mounting of the printing unit in the parallel dispensing device. In terms of the construction, the advantage emerges in particular from the fact that the first transverse axis can constitute a reference axis, on the basis of which the rest of the dispenser nozzles of the printing unit can be aligned and a clearly delimited construction space can be defined. For mounting, the profile of the first transverse axis is advantageous on account of this, since even untrained mounting personnel can draw a conclusion about the alignment in which the printing unit is to be attached and fastened to the device solely by viewing the profile of the first and second dispenser nozzles.

In an advantageous refinement, the printing unit has a center region, in which a multiplicity of dispenser nozzles, comprising the first, second and third dispenser nozzles, are arranged along multiple rows that run parallel to one another, wherein the first and the third dispenser nozzle are arranged in a common first row and the second dispenser nozzle is arranged in another row, and all dispenser nozzles of one row of the center region are evenly spaced apart from one another at the first nozzle spacing.

It is an essential finding of the applicant that it is associated with advantages when the dispenser nozzles of a printing unit are arranged in an even arrangement in relation to one another at least in certain regions, in the present case referred to as center region. This multiplies the advantage according to the invention of two dispenser nozzles arranged in succession in the movement direction.

In this respect, the center region has at least two rows, wherein the first and the third dispenser nozzle are arranged in the first row at the first nozzle spacing in relation to one another. Another row, which is spaced apart from and parallel to the first row, comprises the second dispenser nozzle and at least one further dispenser nozzle, wherein at least that row comprising the two dispenser nozzles has a structure identical to the first row.

If the first dispenser nozzle and the second dispenser nozzle are arranged on the common first transverse axis, a matrix-like arrangement of dispenser nozzles is produced by the uniform spacing between each two adjacent dispenser nozzles of a row.

The advantage of such a matrix-like arrangement is that multiple printed lines that run parallel to one another can be created selectively in the form of a cohesive printed line or a plurality of subsegments that are spaced apart coaxially in relation to one another. This ensues depending on how the relative displacement travel is selected in relation to the first nozzle spacing. By setting a relative displacement travel which is smaller than the first nozzle spacing, the matrix-like arrangement of the dispenser nozzles in the center region, as a result of the printing operation, produces a group of multiple parallel printed lines interrupted by at least one respective gap. By setting a relative displacement travel which corresponds to or is larger than the first nozzle spacing, the matrix-like arrangement of the dispenser nozzles in the center region, as a result of the printing operation, produces a group of multiple parallel printed lines which each extend uninterrupted over that region of the substrate that is to be printed and, if appropriate, each have an overlap region.

It is within the scope of the advantageous refinement that the center region comprises more than two rows of dispenser nozzles and that one of these rows comprises more than two dispenser nozzles. Advantageously, all rows arranged in the center region are evenly spaced apart from one another, with the result that the center region is characterized by a continuous matrix pattern in which the dispenser nozzles are arranged. A matrix pattern of this type is advantageous for the production of the printing unit in particular by means of automated processing methods.

In an advantageous refinement, the number of rows in the center region is at least 60, preferably at least 80, most preferably at least 100.

Investigations by the applicant have shown that the total number of rows, given conventional dimensions of the substrates, in particular semiconductor substrates, that are to be printed, should be at least 60, in order to achieve an above-average increase in productivity over known parallel dispensing devices and methods. In particular, the rows can be distributed over the entire width of the printing unit at uniform spacings, at least in certain regions. In an advantageous refinement, one row of the center region has a total of exactly two dispenser nozzles, which are spaced apart from one another at the first nozzle spacing.

Investigations by the applicant have shown that a good compromise between the production costs of a printing unit and the costs of a drive means can be found when the number of dispenser nozzles within one row of the center region is not greater than two. In particular, this is advantageous when the first nozzle spacing between the dispenser nozzles of a row is approximately half of a substrate dimension that is to be printed, minus any edge distances.

Substrates, in particular semiconductor substrates, that are to be printed generally have a rectangular or cuboidal basic shape with a basic area. They can be printed with printed lines by a plurality of dispenser nozzles arranged in a center region of a printing unit, between two parallel edges of said basic shape, without it being necessary to consider that individual dispenser nozzles might project beyond the substrate. As a result, the peripheries of the substrate could be printed inadvertently or the device could be soiled.

However, there are also substrates that are to be printed that have different dimensions at least in certain regions in the direction of the printed lines that are to be applied. In particular semiconductor substrates can have what is referred to as a pseudo-square shape, apart from a rectangular or cuboidal basic shape. The pseudo-square shape is a rectangular basic shape with beveled (also: rounded) corners. The beveled corners lead to the semiconductor substrate that is to be printed having at least two regions in which the contact-making fingers must be applied in a variety of lengths and/or in different regions.

Known devices and methods solve this technical problem by actively blocking the flow of print medium through individual dispenser nozzles of a printing unit that project beyond the substrate during the printing operation, for example by means of a valve assigned to the corresponding dispenser nozzles. As an alternative or in addition, use is made of templates arranged on the periphery of the substrate and/or on the other side of said periphery, with the result that the exit of print medium from selected dispenser nozzles of a printing unit is prevented in certain regions. Disadvantageously, shut-off valves are associated with high costs and high control complexity, while templates require high cleaning outlay.

In an advantageous refinement of the invention, these disadvantages are eliminated by arranging a fourth dispenser nozzle on a second longitudinal axis, wherein the first longitudinal axis and the second longitudinal axis run spaced apart from and parallel to one another, and the first and the fourth dispenser nozzle are arranged along a common oblique axis, wherein the oblique axis runs at an angle between zero degrees and ninety degrees in relation to the movement direction and the oblique axis delimits the printing unit in such a way that the printing unit is free of further dispenser nozzles on one side of the oblique axis, preferably in a region between the first and the second longitudinal axis.

The second longitudinal axis and the oblique axis, similarly to the first longitudinal axis and the first transverse axis, are imaginary orientation axes along which at least the fourth dispenser nozzle is arranged.

In this case, the orientation of the second longitudinal axis ensures that the fourth dispenser nozzle creates a fourth printed line running parallel to the first printed line during the relative movement by discharging the print medium. Here, the arrangement of the fourth dispenser nozzle is fundamentally no different from the arrangement of the second dispenser nozzle in relation to the first dispenser nozzle. The orientation of the oblique axis, however, ensures that the first and the fourth dispenser nozzle are not at the same height in the movement direction. Since the oblique axis delimits the printing unit in terms of the arrangement of the dispenser nozzles in a similar way to the first transverse axis, the printing unit can be matched to the contours of the substrate that is to be printed preferably in the region between the first and the second longitudinal axis. When carrying out and ending the relative movement, the first and the fourth dispenser nozzle are located exactly at the end of a respective region that is to be printed of the substrate.

Advantageously, when constructing the printing unit, consideration can be given to the angle at which the corners of a substrate with a pseudo-square shape are beveled in relation to the rest of the edges of the substrate, in order to match the profile of the oblique axis and thus also the arrangement of the first and the fourth dispenser nozzle to the profile of the beveled corners of the substrate. In the event of mounting the parallel dispensing device, the arrangement of the first and the fourth dispenser nozzle can also be utilized to align the printing unit with the aid of a substrate that is to be printed, even when this is done by untrained mounting personnel. In this respect, the printing unit can be matched to an edge of the substrate at least on the basis of the oblique axis.

In an advantageous refinement, a fifth dispenser nozzle is arranged on the second longitudinal axis in the movement direction at a second nozzle spacing in relation to the fourth dispenser nozzle, wherein the second longitudinal axis delimits the dispensing unit in such a way that the printing unit is free of further dispenser nozzles on one side of the second longitudinal axis.

Discharging the print medium from the fourth and the fifth dispenser nozzle, similarly to the embodiments relating to the first and the third dispenser nozzle, creates printed lines that, depending on the relative displacement travel of the relative movement, may be formed spaced apart from one another coaxially, with an overlap, or cohesively.

In principle, the first and the second nozzle spacing can be identical or different.

If the printing unit is configured in such a way that the first and the second nozzle spacing are identical, when discharging the print medium through the fourth and the fifth dispenser nozzle it is possible to create an identical pattern of printed lines to that created by discharging the print medium through the first and the third dispenser nozzle.

As a result of a configuration of the printing unit in which the first and the second nozzle spacing are different, the fourth and the fifth dispenser nozzle optionally produce a different printed line pattern to that created by means of the first and the third dispenser nozzle. This depends in particular on what ratio of the relative displacement travel that is set to the first and the second nozzle spacing is selected.

By setting a relative displacement travel which is less than the smaller one of the first and the second nozzle spacing, the two dispenser nozzle pairs create two pairs of printed lines with two respective coaxial printed lines, between which a gap is formed.

By setting a relative displacement travel which corresponds to the smaller one of the first and the second nozzle spacing, the dispenser nozzle pair with the smaller spacing creates a cohesive printed line consisting of two printed lines, whereas the dispenser nozzle pair with the greater spacing creates two printed lines that are spaced apart from one another coaxially.

By setting a relative displacement travel which is larger than the smaller one of the first and the second nozzle spacing, but also is smaller than the larger one of the first and the second nozzle spacing, the dispenser nozzle pair with the smaller spacing creates two cohesive printed lines with an overlap region, whereas the dispenser nozzle pair with the greater spacing creates two printed lines that are spaced apart from one another coaxially.

By setting a relative displacement travel which is larger than the smaller one of the first and the second nozzle spacing and which corresponds at least to the larger one of the first and the second nozzle spacing, the two dispenser nozzle pairs create two cohesive printed lines, each of which has an overlap region, of which one overlap region is longer than the other.

The second longitudinal axis, along which the fourth and the fifth dispenser nozzle are arranged, delimit the arrangement of the dispenser nozzles on the printing unit in such a way that no further printed lines are created on one side of the second longitudinal axis during the printing operation.

In an advantageous refinement, the printing unit has a peripheral region in which a multiplicity of dispenser nozzles, comprising the fourth and the fifth dispenser nozzle, are arranged along at least a first peripheral row, wherein the first peripheral row comprises at least the fourth and the fifth dispenser nozzle, and all dispenser nozzles of the first peripheral row are evenly spaced apart from one another at a second nozzle spacing.

The peripheral region constitutes a region of the printing unit in which the dispenser nozzles can be arranged in a long-range order, similarly to the center region. This long-range order can be achieved in that the dispenser nozzles arranged in the peripheral region are arranged in one or more peripheral rows, similarly to the configuration of the center region. Consequently, the peripheral region comprises at least the first peripheral row, the dispenser nozzles of which are aligned along the second longitudinal axis and the arrangement of which on the printing unit is delimited by the oblique axis.

Particular advantages are associated with the formation of a peripheral region if the substrate that is to be printed is a semiconductor substrate which has a pseudo-square shape. Here, the semiconductor substrate may be arranged in the device in such a way that, during the relative movement, the peripheral region of the printing unit passes over that part of the semiconductor substrate that contains the beveled corners and wherein the center region of the printing unit passes over that part of the semiconductor substrate that, in the movement direction, has a uniform dimension preferably larger than the region with the beveled corners.

Advantageously, the number of dispenser nozzles arranged in a peripheral row of the peripheral region is different to the number of dispenser nozzles arranged in a row of the center region. Advantageously, however, in this case the first nozzle spacing corresponds to the second nozzle spacing, with the result that the only difference between the center region and the peripheral region is the number of dispenser nozzles between a row and a peripheral row. This simplifies mechanical manufacture of the printing unit, since the same machining parameters for the production or later arrangement of the dispenser nozzles can be used for the center region and for the peripheral region.

In an advantageous refinement, the peripheral rows each comprise a total of two dispenser nozzles, which are spaced apart from one another at the second nozzle spacing, wherein the first nozzle spacing is larger than the second nozzle spacing.

Investigations by the applicant have shown that a good compromise between the production costs of a printing unit and the costs of a drive means can be found when the number of dispenser nozzles within one peripheral row of the peripheral region is not greater than two.

By virtue of a difference between the first nozzle spacing and the second nozzle spacing, it is easily possible to segment the substrate in certain regions with two different patterns of printed lines, it being possible, however, to set one and the same relative displacement travel between the printing unit and the substrate.

The aforementioned refinement makes it possible to utilize the peripheral region of the printing unit to print the substrate with a continuous printed line which is assembled from the printed lines created by the fourth and fifth dispenser nozzle. At the same time, the center region of the printing unit can be utilized to create a plurality of printed lines which have a respective interruption in the form of a gap after the printing operation has finished. Said gaps can advantageously be utilized to apply a data matrix code or as an intended interruption for creating a half-cell in the case of a printed semiconductor substrate.

In an advantageous embodiment, the printing unit has at least a first axis of symmetry and/or a second axis of symmetry, wherein the first axis of symmetry runs parallel to the movement direction and the second axis of symmetry runs orthogonally in relation to the movement direction, and wherein the dispenser nozzles are arranged on the printing unit axially symmetrically at least in terms of the first or the second axis of symmetry.

The advantage of an axially symmetrical arrangement of the dispenser nozzles on the printing unit lies in the easy construction and producibility of the printing unit. During the construction, this advantage manifests in the fact that preferably it is necessary to construct only half of the printing unit in terms of the positions of the dispensing nozzles, and the respective other half is formed in accordance with the first half. If the printing unit has the second axis of symmetry, the construction outlay is reduced further.

A symmetrical arrangement of the dispenser nozzles is also associated with advantages when the substrate that is to be printed likewise has an axially symmetric structure. This is the case in particular for a pseudo-square shape of a semiconductor substrate that is to be printed. To apply a plurality of printed lines, the printing unit, of which the arrangement of dispenser nozzles is delimited by the first transverse unit and/or the second longitudinal axis and/or the oblique axis, can be arranged completely above the substrate. Owing to the symmetrical structure of the printing unit, with a suitable selection of the overall dimensions, when printing a likewise symmetric substrate it can be ensured that no dispenser nozzle projects beyond the substrate throughout the relative movement.

In an advantageous refinement, the printing unit comprises at least two subunits, wherein a first subunit and a second subunit each comprise some of all the dispenser nozzles of the dispenser unit, and the drive means is configured to move the first and the second subunit independently of one another to generate the relative movement.

The dispenser unit can in principle be dividable into any desired number of subunits that can be moved independently of one another. The relative movement is composed in this case of a multiplicity of partial movements, during which the corresponding subunit is displaced in relation to the substrate, or vice versa. The partial movements in this case each take place in the movement direction.

If the printing unit has a center region and a peripheral region, the first subunit can comprise the center region and the second subunit can comprise the peripheral region of the printing unit. It is furthermore also possible for only the center region and/or the peripheral region to be divided into at least two subunits in each case.

It is also within the scope of the advantageous refinement that at least the first and the second subunit are separated by an axis of symmetry of the printing unit. This is associated with advantages in terms of the construction of the subunits, since only one subunit needs to be constructed, while the respective other subunit merely needs to be formed symmetrically in relation to the already constructed subunit.

In an advantageous refinement, the printing unit comprises a print medium inlet and at least one print medium channel, wherein the print medium inlet is fluidically connected to a central shut-off valve and at least one nozzle rail is arranged exchangeably in the region of the print medium channel, wherein the nozzle rail comprises at least some of the dispenser nozzles of the printing unit.

The print medium inlet serves to fluidically connect the printing unit to a print medium supply unit and to conduct the print medium through at least one print medium channel to a plurality of dispenser nozzles, which deliver the print medium to the substrate.

The central shut-off valve may be in the form of an electrically actuable valve, which is opened at the beginning of the relative movement, during which the substrate is printed with a plurality of printed lines, and is closed when the relative movement has finished.

The nozzle rail comprises at least some of the dispenser nozzles and is arranged exchangeably in the region of the pressure medium channel. Said exchangeability can be designed as a form fit, for example by a snap-fit connection, or as a force fit, for example by a clamping connection, in the region of the print medium channel. This allows the nozzle rail to be able to be exchanged for another nozzle rail with low effort. The easy exchangeability allows a high degree of availability of the printing device in the industrial printing of substrates, in particular semiconductor substrates.

The invention also relates to a method for parallel dispensing of a print medium onto a substrate, in particular for producing one or more conductor tracks on a semiconductor substrate, having a printing unit and a drive means, wherein the drive means generates a relative movement between the printing unit and the substrate with a movement direction, wherein the print medium is discharged simultaneously through a first dispenser nozzle and a second dispenser nozzle and a third dispenser nozzle, and as a result reaches the substrate, wherein the first dispenser nozzle creates a first printed line with a first starting point and a first end point, and the second dispenser nozzle creates a second printed line with a second starting point and a second end point, wherein the first and the second printed line are applied to the substrate spaced apart and parallel to one another.

It is essential for the method according to the invention that the third dispenser nozzle creates a third printed line with a third starting point and a third end point, wherein the first printed line runs coaxially with the third printed line, and the first starting point is spaced apart from the third starting point at a first nozzle spacing.

Advantageously, the device according to the invention or one of its advantageous refinements is configured to carry out the method according to the invention.

The method according to the invention makes it possible to considerably increase productivity when printing a substrate, in particular a semiconductor substrate.

In an advantageous refinement, to perform the relative movement, a relative displacement travel, which is smaller than the first nozzle spacing in a first method alternative, is set and a gap is formed between the first and the third printed line.

The gap between the first and the third printed line can be used to apply an identifier of the printed substrate, for example a data matrix code. The print medium is preferably an electrically conductive paste, which is applied to a semiconductor substrate in order to form electrically conductive contact-making fingers. The formation of the gap makes it possible to segment the semiconductor substrate in the regions of the first and the third printed line.

In an advantageous refinement, to perform the relative movement, a relative displacement travel, which corresponds to at least the first nozzle spacing in a first method alternative, is set and the first printed line and the third printed line are formed with a common contact region, in particular an overlap region.

A contact region between the first and the third printed line allows the creation of a continuous printed line, which is assembled from the first and the third printed line. This halves the time required to create an assembled printed line of this type. If the printed lines are electrical contact lines, the overlap region increases the electrical conductivity of the assembled printed line that is created.

### BRIEF DESCRIPTION OF THE DRAWINGS

Further preferred features and embodiments of the device according to the invention and of the method according to the invention will be discussed below on the basis of exemplary embodiments and the figures. The exemplary embodiments are merely advantageous configurations of the invention and are not limiting.

In the figures:

FIG. 1 shows a side view of a parallel dispensing device;

FIG. 2 shows a plan view of a parallel dispensing device, with a first variant of a printing unit;

FIG. 3 shows a second variant of a printing unit;

FIG. 4 shows two substrates which are printed in different ways by means of the two variants of the printing unit;

FIG. 5 shows a third variant of a printing unit; and

FIG. 6 shows a substrate which is printed by means of the third variant of a printing unit.

### DETAILED DESCRIPTION

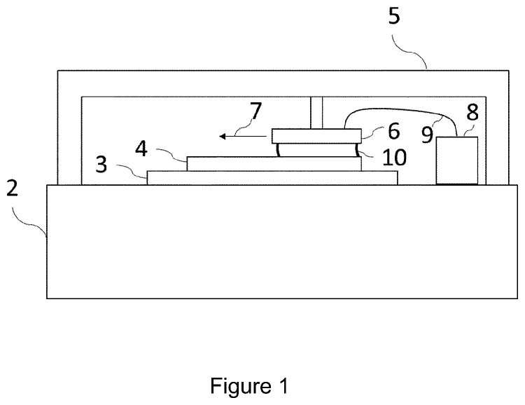

FIG. 1 shows a parallel dispensing device 1. The device 1 comprises a machine bed 2 and a substrate support 3, which is arranged thereon and serves to receive a substrate 4 that is to be printed and to fix it in a defined position and alignment for a printing operation. A drive means in the form of a linear unit 5 is arranged on a frame above the substrate support 3 and the substrate 4 located thereon. The linear unit 5 has a movable carriage, by means of which an exchangeable first printing unit 6 can be moved in relation to the substrate support 3 and the substrate 4. The substrate 4 is a semiconductor structure, in the present case a semiconductor structure for forming a photovoltaic solar cell.

The device 1 also has a print medium reservoir 8 with a delivery unit, not shown, which is fluidically connected to the first printing unit 6 via a delivery line 9. The delivery unit may be in the form of a pump device, for example a piston pump, which delivers a print medium 10 located in the print medium reservoir 8 to the first printing unit 6. In this respect, the print medium 10 reaches a plurality of dispenser nozzles (not shown) of the first printing unit 6, which dispenser nozzles deliver the print medium to the surface of the substrate 4. In the process, a plurality of printing lines are created, at least two of which run coaxially with one another. The print medium 10 is a metallic printing paste for creating electrically conductive contact fingers on the substrate 4.

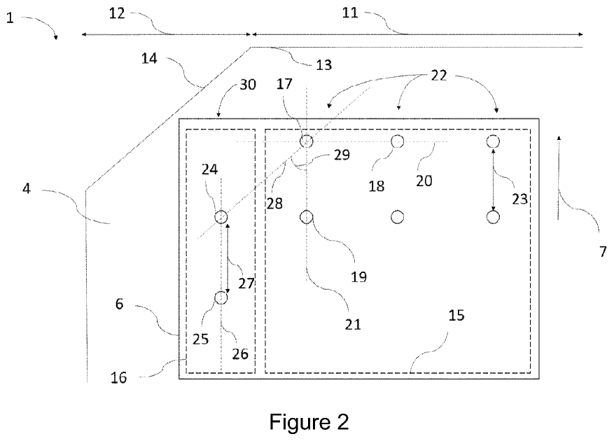

FIG. 2 shows a plan view of the first printing unit 6 and the substrate 4 of FIG. 1. For better clarity, the rest of the constituent parts of the device 1 as per FIG. 1 are not shown.

In a manner corresponding to the embodiments relating to FIG. 1, the first printing unit 6 is located above the substrate 4 and is moved in relation to the substrate in the movement direction 7.

The substrate 4 has a pseudo-square shape. This allows the substrate 4 to be subdivided into a first region 11 and a second region 12. In the first region 11, the substrate 4 is delimited by a straight edge 13, which runs orthogonally in relation to the movement direction 7 in the arrangement of the substrate 4 that is shown. In the second region 12, said straight edge of the first region 11 leads to a bevel 14, which is angled away from the straight edge 13 by 45° .

The printing unit 6 is equipped with a center region 15 and a peripheral region 16. During the relative displacement of the printing unit 6, it passes over the first region 11 of the substrate 4 by way of the center region 15, whereas the peripheral region 16 passes over the second region 12 of the substrate 4.

In the center region 15, the printing unit 6 has a first dispenser nozzle 17, a second dispenser nozzle 18 and a third dispenser nozzle 19. The first dispenser nozzle 17 and the second dispenser nozzle 18 are arranged along a common first transverse axis 20, which runs orthogonally in relation to the movement direction 7. The first dispenser nozzle 17 and the third dispenser nozzle 19 are arranged along a common first longitudinal axis 21, which runs parallel to the movement direction 7.

In addition to the aforementioned dispenser nozzles 17, 18, 19, further dispenser nozzles are arranged in multiple rows 22 in the center region 15. In said rows 22, the dispenser nozzles are evenly spaced apart from one another at a first nozzle spacing 23.

In the peripheral region 16, a fourth dispenser nozzle 24 and a fifth dispenser nozzle 25 are arranged along a common second longitudinal axis 26. The second longitudinal axis 26, similarly to the first longitudinal axis 21, runs parallel to the movement direction 7. In the exemplary embodiment as per FIG. 2, the fourth and the fifth dispenser nozzle 24 and 25, respectively, are the only dispenser nozzles arranged spaced apart from one another in a peripheral row 30 of the peripheral region 16 at a second nozzle spacing 27.

Furthermore, the first dispenser nozzle 17 and the fourth dispenser nozzle 24 are arranged along a common oblique axis 28, which runs at an acute angle 29 in relation to the movement direction 7.

If the printing unit 6 is displaced along the movement direction 7 in relation to the substrate 4, the dispenser nozzles arranged in the center region 15 are at least partially upstream of those dispenser nozzles arranged in the peripheral region 16. This results in the advantage that the dispenser nozzles arranged in the peripheral region 16 do not project beyond the substrate 4 between the first printing unit 6 and the substrate 4 after the relative movement has finished, which would result in print medium being wasted.

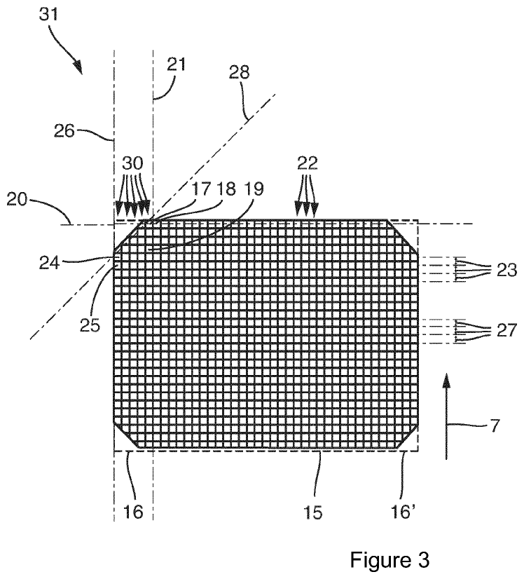

FIG. 3 shows an alternative exemplary embodiment for a printing unit in the form of a second printing unit 31, which, however, is structured in accordance with the same geometric principles as the first printing unit 6 as per FIG. 2. To illustrate the identity between the geometric principles, use is made at least in part of the same reference signs as in FIG. 2.

The second printing unit 31, similarly to the first printing unit 6 as per FIG. 2, has a center region 15 in which a plurality of dispenser nozzles, comprising a first dispenser nozzle 17, a second dispenser nozzle 18 and a third dispenser nozzle 19, are arranged evenly spaced apart in rows 22. The spacings between two adjacent dispenser nozzles arranged within a row 22 of the center region 15 each correspond to a first nozzle spacing 23.

Furthermore, the second printing unit 31 has two peripheral regions 16 and 16′, which each adjoin the center region 15. In the peripheral regions 16 and 16′, the dispenser nozzles are arranged mirror-symmetrically in relation to one another. In this respect, the dispenser nozzles of a peripheral region are arranged in multiple peripheral rows 30 (shown only in relation to peripheral region 16), in which they are evenly arranged at a second nozzle spacing 27 in relation to one another, the first and the second nozzle spacing 23 and 27, respectively, being identical.

The number of dispenser nozzles of a row 22 of the center region 15 is higher than the number of dispenser nozzles of a peripheral region 30 of a peripheral region 16 or 16′.

The first dispenser nozzle 17 is arranged with the second dispenser nozzle 18 on a common first transverse axis 20, which runs orthogonally in relation to the movement direction 7. Furthermore, the first dispenser nozzle 17 is arranged with the third dispenser nozzle 19 along a common first longitudinal axis 21, which runs parallel to the movement direction 7. The fourth dispenser nozzle 24 is arranged with the fifth dispenser nozzle 25 along a second longitudinal axis 26, which runs parallel to the movement direction 7. In addition, the first dispenser nozzle 17 is arranged on a common oblique axis 28 with the fourth dispenser nozzle 24.

The first transverse axis 20, the second longitudinal axis 24 and the oblique axis 28 delimit the second printing unit 21 in such a way that no dispenser nozzles are arranged on a respective side of the axes mentioned.

The second printing unit 31, in the arrangement in which the dispenser nozzles are arranged thereon, has a completely symmetrical structure along a first axis of symmetry, which runs parallel to the movement direction, and along a second axis of symmetry, which runs orthogonally in relation to the movement direction 7.

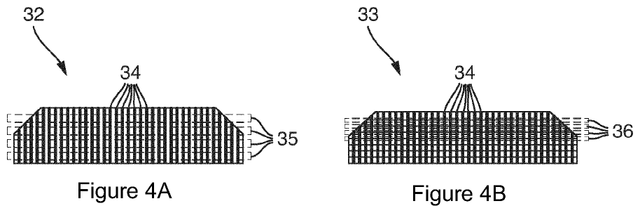

If the second printing unit 31 is moved in a relative movement with the movement direction 7 in relation to a substrate that is to be printed, with a print medium being discharged through the dispenser nozzles, the printed patterns shown in FIG. 4A and FIG. 4B are produced depending on the relative displacement travel that is set between the second printing unit 31 and the substrate.

FIG. 4A shows a first semiconductor substrate 32 which is printed by means of a device in the case of which the relative movement was performed between the second printing unit 31 (corresponding to FIG. 3) with a relative displacement travel which is greater than the first nozzle spacing 23 and the second nozzle spacing 27. The print medium, which during the printing was discharged from the dispenser nozzles of the second printing unit 31 and reached the surface of the semiconductor substrate 32, in the process created a plurality of printed lines 34 that run parallel to one another. The profiles of said printed lines 34 have a respective plurality of overlap regions 35. The overlap regions 35 are produced by at least two dispenser nozzles arranged in succession in the movement direction passing over one and the same region of the semiconductor substrate 32 during the application of the print medium. The print lines 34 are electrically conductive contact fingers, so that the overlap regions 35 serve to bring about a low ohmic resistance between two coaxially adjacent printed lines.

FIG. 4B shows a second semiconductor substrate 33 which was likewise printed by means of a device in the case of which the relative movement was performed between the second printing unit 31 (corresponding to FIG. 2) with a relative displacement travel which, however, is smaller than the first nozzle spacing 23 and the second nozzle spacing 27. The print medium, which during the printing was discharged from the dispenser nozzles of the second printing unit 31 and reached the surface of the semiconductor substrate 33, in accordance with the embodiments relating to FIG. 4A created a plurality of printed lines 34 that run parallel to one another but, by contrast to the semiconductor substrate 32 as per FIG. 4A, are each interrupted by a plurality of gaps 36.

The gaps 36 can serve to electrically contact the interrupted contact finger segments independently of one another by means of one or more busbars or to apply a marking, for example in the form of a data matrix code, to the substrate.

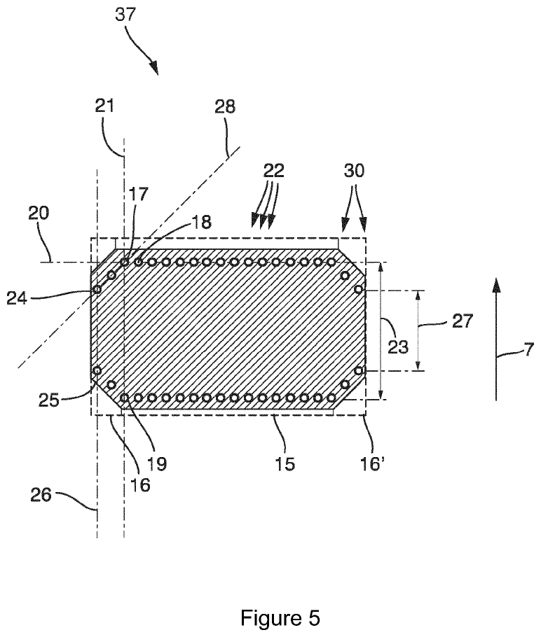

FIG. 5 shows an alternative exemplary embodiment for a printing unit in the form of the third printing unit 37, which is structured in accordance with the same geometric principles as both the first printing unit 6 as per FIG. 2 and the second printing unit 31 as per FIG. 3. To illustrate the identity between the geometric principles, use is made of the same reference signs as in FIGS. 2 and 3, unless mentioned otherwise.

The third printing unit 37, similarly to the first printing unit 6 as per FIG. 2 and similarly to the second printing unit 31 as per FIG. 3, has a center region 15 in which a plurality of dispenser nozzles, comprising a first dispenser nozzle 17, a second dispenser nozzle 18 and a third dispenser nozzle 19, are arranged evenly spaced apart in rows. The spacings between two adjacent dispenser nozzles arranged within a row of the center region 15 correspond to a first nozzle spacing 23.

Furthermore, the third printing unit 37, similarly to the second printing unit 21, has two peripheral regions 16 and 16′, which each adjoin the center region 15. The peripheral regions 16 and 16′ have dispenser nozzles which are arranged mirror-symmetrically in terms of both peripheral regions 16, 16′. The dispenser nozzles of a peripheral region 16 or 6′ are arranged in multiple peripheral rows 30 (shown only in relation to the peripheral region 16), in which, by contrast to the second printing unit 31 as per FIG. 3, they are unevenly arranged at various spacings that are smaller than the first nozzle spacing 23.

The first dispenser nozzle 17 is arranged with the second dispenser nozzle 18 on a common first transverse axis 20, which runs orthogonally in relation to the movement direction 7. Furthermore, the first dispenser nozzle 17 is arranged with the third dispenser nozzle 19 along a common first longitudinal axis 21, which runs parallel to the movement direction 7. The fourth dispenser nozzle 24 is arranged with the fifth dispenser nozzle 25 along a second longitudinal axis 26, which runs parallel to the movement direction 7. In addition, the first dispenser nozzle 17 is arranged on a common oblique axis 28 with the fourth dispenser nozzle 24.

The first transverse axis 20, the second longitudinal axis 24 and the oblique axis 28 delimit the third printing unit 37 in such a way that no dispenser nozzles are arranged on a respective side of the axes mentioned.

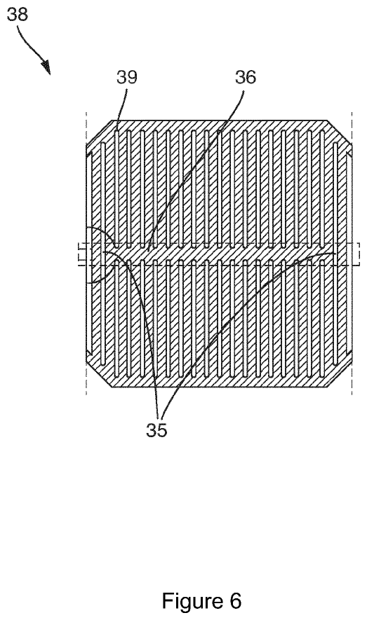

If the third printing unit 37 is moved in a relative movement with the movement direction 7 in relation to a substrate that is to be printed, a print medium being deposited onto the substrate through the dispenser nozzles, a printed pattern as per FIG. 6 is produced in the event of a relative displacement travel which is smaller than the first nozzle spacing but is larger than the spacing between the dispenser nozzles in the peripheral regions.

FIG. 6 shows a semiconductor substrate 38 which was printed by means of a device in the case of which the relative movement was performed between the third printing unit 37 (corresponding to FIG. 5). The print medium, which during the printing was deposited onto the semiconductor substrate 38 from the dispenser nozzles of the third printing unit 37, in the process created a plurality of printed lines 39 that run parallel to one another. The profiles of said printed lines 39 have both a plurality of overlap regions 35 and a plurality of gaps 36, which were created in a single method step by just one relative movement between the semiconductor substrate 38 and the third printing unit 37.

1. A device (1) for parallel dispensing a print medium (10) onto a substrate (4), the device comprising:
a printing unit (6), which comprises a plurality of dispenser nozzles (17, 18, 19, 24, 25) for simultaneous discharge of the print medium (10), and a drive (5) configured to generate a relative movement between the printing unit (6) and the substrate (4) in a movement direction (7);
wherein at least a first one of the dispenser nozzles (17) and a second one of the dispenser nozzles (18) are arranged spaced apart from one another transversely in relation to the movement direction (7); and
the first dispenser nozzle (17) and a third one of the dispenser nozzles (19) of the printing unit (6) are arranged spaced apart from one another along a common first longitudinal axis (21) at a first nozzle spacing (23), and the first longitudinal axis (21) runs parallel to the movement direction (7).

2. The device as claimed in claim 1, wherein
the first dispenser nozzle (17) and the second dispenser nozzle (18) are arranged along a common first transverse axis (20), wherein the first transverse axis (20) runs orthogonally in relation to the movement direction (7) and the first transverse axis (20) delimits the printing unit (6) such that the printing unit (6) is free of further dispenser nozzles on one side of the first transverse axis (20).

3. The device as claimed in claim 1, wherein
the printing unit (6) has a center region (15), in which a multiplicity of the dispenser nozzles, comprising the first, second and third dispenser nozzles (17, 18 and 19, respectively), are arranged along multiple rows (22) that run parallel to one another, the first nozzle and the third dispenser nozzle are arranged in a common first row and the second dispenser nozzle (18) is arranged in another row, and all of the dispenser nozzles of one said row in the center region (15) are evenly spaced apart from one another at the first nozzle spacing (23).

4. The device as claimed in claim 3, wherein
a number of the rows in the center region (15) is at least 60.

5. The device as claimed in claim 3, wherein
each said row in the center region (15) comprises a total of two of the dispenser nozzles, which are spaced apart from one another at the first nozzle spacing (23).

6. The device as claimed in claim 1, further comprising
a fourth dispenser nozzle (24) arranged on a second longitudinal axis (26), wherein the first longitudinal axis (21) and the second longitudinal axis (26) run spaced apart from and parallel to one another, and the first and the fourth dispenser nozzle are arranged along a common oblique axis (28), wherein the oblique axis (28) runs at an angle between zero degrees and ninety degrees in relation to the movement direction and the oblique axis (28) delimits the printing unit (6) such that the printing unit (6) is free of further dispenser nozzles on one side of the oblique axis.

7. The device as claimed in claim 6,
a fifth dispenser nozzle (25) arranged on the second longitudinal axis (26) at a second nozzle spacing (27) in relation to the fourth dispenser nozzle (24), and the second longitudinal axis (26) delimits the printing unit (6) such that the printing unit (6) is free of further dispenser nozzles on one side of the second longitudinal axis (26).

8. The device as claimed in claim 7, wherein
the printing unit (6) has a peripheral region (16) in which a multiplicity of the dispenser nozzles, comprising the fourth nozzle and the fifth dispenser nozzle, are arranged along at least a first peripheral row, the first peripheral row comprises at least the fourth nozzle and the fifth dispenser nozzle, and all of the dispenser nozzles of the peripheral rows arranged in the peripheral region (16) are evenly spaced apart from one another at the second nozzle spacing (27).

9. The device as claimed in claim 8, wherein
the peripheral rows each comprise a total of two of the dispenser nozzles, which are spaced apart from one another at the second nozzle spacing (27) and the first nozzle spacing (23) is larger than the second nozzle spacing (27).

10. The device as claimed in claim 1, wherein
the printing unit (6) has at least one of a a first axis of symmetry or a second axis of symmetry, the first axis of symmetry runs parallel to the movement direction and the second axis of symmetry runs orthogonally in relation to the movement direction, and the dispenser nozzles are arranged on the printing unit (6) axially symmetrically at least in terms of the first or the second axis of symmetry.

11. The device as claimed in claim 1, wherein
the dispenser unit (6) comprises at least two subunits, wherein a first one of the subunits and a second one of the subunits each comprise some of the dispenser nozzles of the dispenser unit (6), and the drive (5) is configured to move the first subunit and the second subunit independently of one another to generate the relative movement.

12. The device as claimed in claim 1, wherein
the printing unit (6) comprises a print medium inlet and a print medium channel, the print medium inlet is fluidically connected to a central shut-off valve and at least one nozzle rail is arranged in a region of the print medium channel, and the nozzle rail comprises at least some of the dispenser nozzles of the printing unit.

13. A method for parallel dispensing of a print medium (10) onto a substrate (4), the method comprising:
providing a printing unit (6) and a drive (5);
the drive generating (5) generates a relative movement between the printing unit (6) and the substrate (4) with a movement direction (7);
simultaneously discharging the print medium (10) through a first dispenser nozzle (17) and a second dispenser nozzle (18) and a third dispenser nozzle (19), which are arranged on the printing unit (6), and as a result reaches the substrate (4);
the first dispenser nozzle (17) creating a first printed line with a first starting point and a first end point, and the second dispenser nozzle creating a second printed line with a second starting point and a second end point, wherein the first and the second printed line are applied to the substrate spaced apart and parallel to one another;
the third dispenser nozzle (19) creating a third printed line with a third starting point and a third end point, wherein the first printed line runs coaxially with the third printed line; and
spacing apart the first starting point from the third starting point at a first nozzle spacing (23).

14. The method as claimed in claim 13, wherein
to perform the relative movement, a relative displacement travel, which is smaller than the first nozzle spacing (23) is set and a gap (36) is formed between the first and the third printed line.

15. The method as claimed in claim 13, wherein
to perform the relative movement, a relative displacement travel, which corresponds to at least the first nozzle spacing (23), is set and the first printed line and the third printed line are formed with a common contact region.
